(19) United States
(12) Patent Application Publication
(10) Pub. No.: US 2005/0224936 A1
(43) Pub. Date: Oct. 13, 2005

(54) CHIP PACKAGE STRUCTURE

(76) Inventors: Jeng-Dah Wu, Kaohsiung City (TW); Yi-Shao Lai, Taipei County (TW); Chang-Lin Yeh, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,675

(22) Filed: Apr. 12, 2005

(30) Foreign Application Priority Data
Apr. 12, 2004 (TW) 93110065

(51) Int. Cl. H01L 23/02

(52) U.S. Cl. 257/678

(57) ABSTRACT

A chip package includes a package substrate, a chip and a molding compound. The package substrate has a carrying surface and a back surface opposite to the carrying surface. The chip is mounted on the carrying surface and electrically connected to the package substrate. Furthermore, the molding compound is applied over the carrying surface to cover the chip and a part of the package substrate. The outline of a juncture between the molding compound and the package substrate is a smooth closed curve so that thermal stress is uniformly distributed over the juncture to prevent stress concentration. The reliability of the package structure is thereby improved.

### CROSS-REFERENCE TO RELATED APPLICATION

This application claims the priority benefit of Taiwan application serial no. 93110065, filed on Apr. 12, 2004. All disclosure of the Taiwan application is incorporated herein by reference.

### BACKGROUND OF THE INVENTION

1. Field of the Invention

The present invention relates to a chip package structure, and particularly to a chip package structure in which an outline of a juncture between a molding compound and a package substrate is a close curve with no sharp corner.

2. Brief Description of Related Art

Recently, along with the rapid technical development of electronic devices and the semiconductor industry, electronic products that are more user-friendly and with better performance are continuously placed in the market. Further, these products are designed to be lightweight and more compact than before. In the semiconductor industry, the production of integrated circuit (IC) includes three stages: IC design, IC production and IC package. In IC packaging, a bare chip is obtained via wafer production, circuit design, mask formation and wafer sawing. Each bare chip obtained by sawing the wafer is electrically connected to a substrate via bonding pads formed on the chip. A molding compound encapsulates the chip to protect the bare chip from being polluted by dusts and being adversely affected by external moisture, while an electric interconnect between the chip and an external device is maintained. A chip package is thus completed.

For a high-pin-count IC device, a ball grid array package may provide a great amount of contacts, an improved heat dissipation and good electric properties. The ball grid array package thus becomes popular in the chip package field. In a ball grid array package, a bare chip is electrically connected to a package substrate via wires or bumps by means of wire bonding or the flip chip bonding technology. The substrate is then electrically and physically connected to a large printed circuit board via solder balls so that signal transmission between interfaces, devices and terminals, respectively on the substrate and the printed circuit board can be achieved by the solder balls.

Furthermore, depending on the types of the substrate, the ball grid array can be divided into plastic-BGA package (PBGA package), ceramic-BGA package (CBGA package) and tape-BGA package (TBGA package) in which a tape with patterns thereon is directly attached to the chip.

FIG. 1A and FIG. 1B are a respectively top view and a cross-sectional view of a conventional ball grid array package. A chip package 100 includes a chip 110, a package substrate 120, a plurality of solder balls 130 and a molding compound 140. The chip 110 is mounted on a first surface of the package substrate 120. The chip 110 has a plurality of bonding pads 112 which are respectively electrically connected to contacts 122 on the package substrate 120 via wire bonding. Furthermore, the solder balls 130 are formed on a second surface of the package substrate 120 opposite to the first surface. The solder balls 130 are electrically connected to the chip 110 through the package substrate 120 to provide an electric interconnect between the chip and an external circuit (not shown). The bonding pads 112 are connected to the contacts 122 through a plurality of wires 150. The molding compound 140 is applied over the first surface of the package substrate 120 to cover the chip 110, the contacts 122 and the wires 150. As a result, the chip is prevented from being affected by the environment and the wires 150 are protected from being damaged.

In a conventional chip packaging, the molding compound is formed by providing a molding compound material, such as epoxy resin, which is a semi-solid at high temperature, molding and cooling the molding compound material to form the molding compound enclosing the chip. However, since the coefficients of thermal expansion (CTE) of the chip, the package substrate and the molding compound are different, thermal stress will generate during the packaging process or the subsequent reliability test or the actual operation due to temperature differences. Thermal stress is also generated at the junctures between the three different materials (chip, package substrate and molding compound), especially at the corners of the molding compound. Therefore, the patterned wirings located at the corners of the molding compound tend to be damaged, or delamination between the molding compound and the substrate occurs. Consequently, chip default and deterioration in yield are resulted.

### SUMMARY OF THE INVENTION

Therefore, it is an object of the invention to provide a chip package structure in which an outline of a juncture between a molding compound and a package substrate is a smooth closed curve, so that thermal stress is uniformly distributed to prevent stress concentration. The reliability of the chip package structure is thereby improved.

In order to achieve the above and other objectives, the chip package structure of the invention includes a package substrate, a chip and a molding compound. The package substrate has a carrying surface and a back surface opposite to the carrying surface. The chip is mounted on the carrying surface and electrically connected to the package substrate. Furthermore, the molding compound is applied over the carrying surface to cover the chip and a part of the package substrate. The outline of the juncture between molding compound and the package substrate is a smooth closed curve so that thermal stress is uniformly distributed to prevent stress concentration, and thereby the reliability of the package structure is improved.

In one preferred embodiment of the invention, the outline of the juncture between the molding compound and the package substrate is a circle, an ellipse, a polygon with rounded corners, or other rounded shapes. The chip package structure further includes a plurality of solder balls mounted on the back surface of the package substrate and electrically connected to the chip via the package substrate to complete a ball grid array package.

In one preferred embodiment of the invention, the connection between the chip and the package substrate is achieved by a plurality of wires. The molding compound covers the wires. Alternatively, the electric and mechanic connection between the chip and the package substrate is achieved via a plurality of bumps by the flip chip interconnect technology. The molding compound can be, for example, polymer resin.

As described above, the molding compound of the chip package structure of the invention has rounded corners to prevent stress concentration. Since the outline of the juncture between the molding compound and the package substrate is a smooth closed curve, thermal stress can be uniformly distributed over the juncture to prevent any delamination or damage of the patterned wirings. The reliability of the chip package structure is thus improved.

### BRIEF DESCRIPTION OF THE DRAWINGS

FIGS. 1A and 1B are respectively a top view and a cross-sectional view of a conventional ball grid array package structure.

FIGS. 2A and 2B are respectively a top view and a cross-sectional view of a ball grid array package structure according to one embodiment of the invention.

FIG. 3 is a top view of a chip package structure with a molding compound according to one embodiment of the invention.

FIG. 4 is a top view of chip package structure with a molding compound according to another embodiment of the invention.

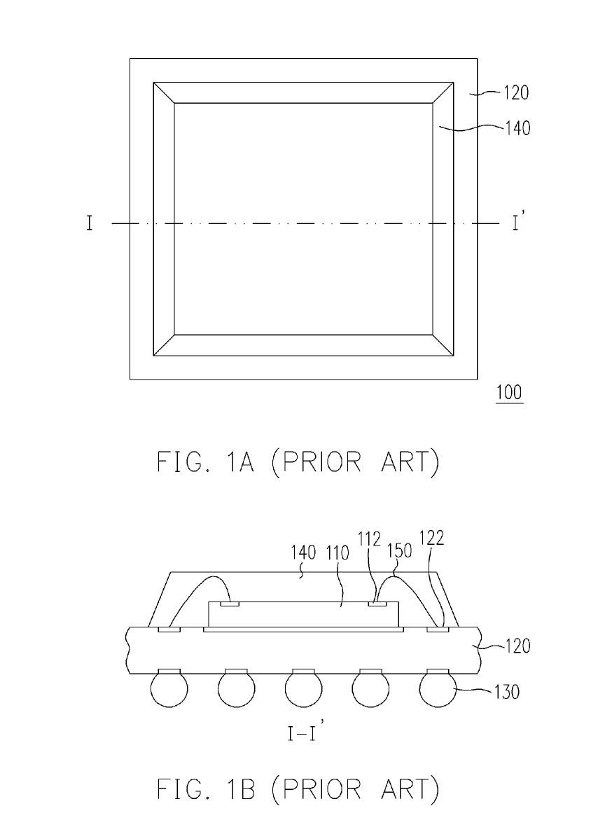

### DETAILED DESCRIPTION OF THE PREFERRED EMBODIMENTS

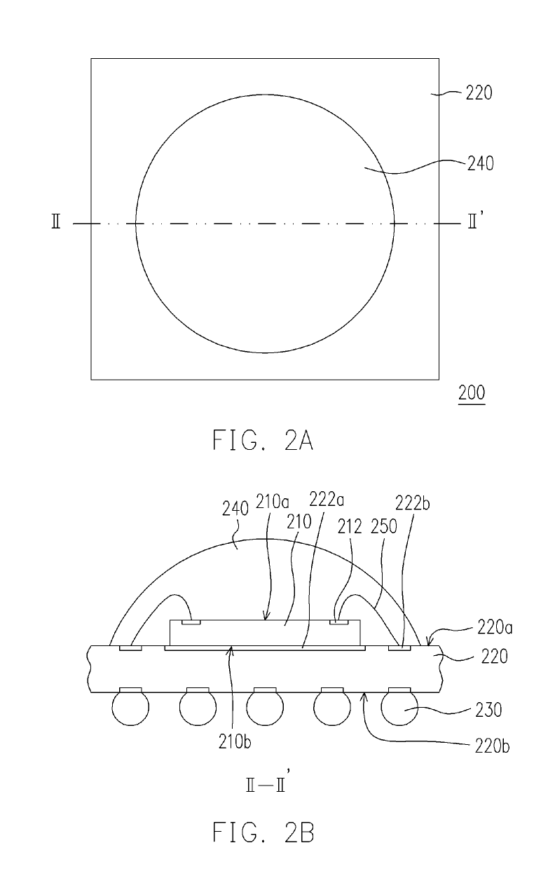

FIG. 2A-2B are respectively a top view and a cross-sectional view of a ball grid array package structure according to one embodiment of the invention. A chip package structure 200 includes a chip 210, a package substrate 220 and a plurality of solder balls 230 and a molding compound 240. The package substrate 220 has a first surface 220a and a second surface 220b. The first surface 220a is further provided with a die pad 222a and a plurality of contacts 222b around the die pad 222a. The chip 210 has an active surface 210a and a back surface 210b opposite to the active surface 210a. A plurality of bonding pads 212 are formed on the active surface 210a. The back surface 210b of the chip 210 is attached onto the die pad 222a of the package substrate 220, so that heat generated from the operation of the chip 210 is dissipated from the chip 210 via the die pad 220a. Furthermore, the bonding pads 212 of the chip 210 are respectively electrically connected to the contacts 222b of the package substrate 220 via a plurality of wires 250. The solder balls 230 are mounted on the second surface 220b of the package substrate 220.

Still referring FIGS. 2A and 2B, the molding compound 240 is applied over the first surface 220a of the package substrate 220. The molding compound 240 covers the chip 210, the contacts 222b of the package substrate 220 and the wires 250 to protect the chip 210 and the wires 250. The molding compound 240 can be a polymeric resin, and preferably a resin filled with a low CTE (coefficient of thermal expansion) filler, such as silicon dioxide particles, aluminum oxide particles, boron nitride particles, graphite fibers or other inorganic particles to reduce the internal stress between the molding compound 240 and the chip 210 and between the molding compound 240 and the package substrate 220. In order to overcome the stress concentration that occurs in the art, the molding compound 240 has a profile of a dome and the outline of the juncture between the molding compound 240 and the package substrate 220 is a smooth closed curve. The thermal stress resulting from a dismatch of the thermal expansion coefficients between the molding compound 240 and the package substrate 220 can be uniformly distributed over the juncture. Therefore, the thermal stress can be prevented from concentrating at specific areas and the bonding of the molding compound 240 to the package substrate 220 can be improved.

It is noted that the connection between the chip and the package substrate is achieved by a plurality of wires. The molding compound covers the wires. Alternatively, the electric and mechanic connection between the chip and the package substrate is achieved via a plurality of bumps by the flip chip interconnect technology. The features of the invention can be also applied to other packaging technologies.

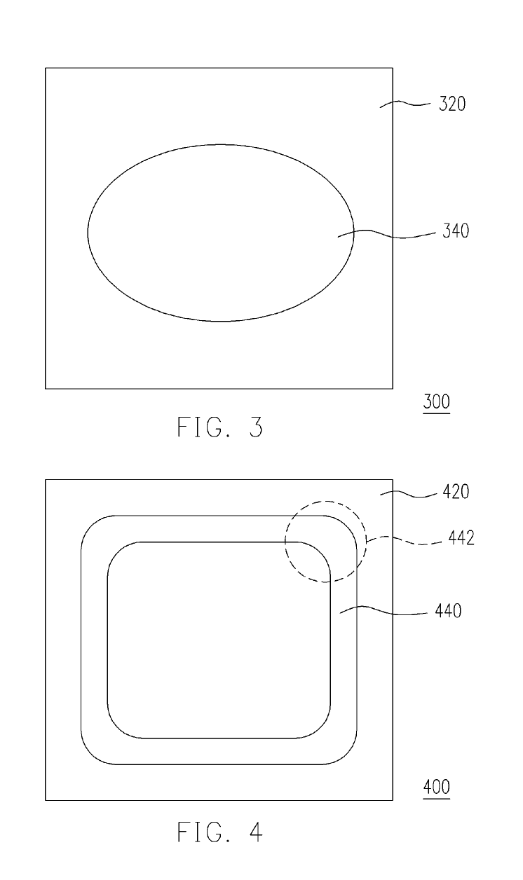

The outline of the juncture between the molding compound and the package substrate is not limited to a circle. FIG. 3 is a top view of a chip package structure 300 with a molding compound 340 according to one embodiment of the invention. FIG. 4 is a top view of a chip package structure 400 with a molding compound 440 according to another embodiment of the invention. In FIG. 3, the outline of the juncture between the molding compound 340 and the package substrate is an ellipse, while in FIG. 4 the outline of the juncture is of a polygon. The polygonal outline of the juncture has rounded corners 442 so as to prevent stress concentration.

In other words, the outline of the juncture between the molding compound and the package substrate is of various smooth closed curved profiles such as circle, ellipse or polygon with rounded corners. The molding compounds can be of pillar, conical, polygonal column or semi-spherical shapes. For example, the molding compound shown in FIGS. 2A and 2B are of semi-spherical shape while the outline of the juncture is of a circle shape. In some applications, the outline of the molding compound can be pillar or conical shape.

In view of foregoing, the chip package structure of the invention modifies the outline of the molding compound in a manner that the outline of the juncture between the molding compound and the package substrate is a smooth closed curve. The profile and the size of the molding compound vary according to the design demands and the actual applications.

The chip package structure according to the invention provides the following advantages.

1. The thermal stress is uniformly distributed to prevent any stress concentration at the outline of the juncture between the molding compound and the package substrate to protect the patterned wirings on the package substrate.

2. Any delamination due to a non-uniform distribution of thermal stress between the molding compound and the package substrate can be prevented.

3. The yield of the chip packaging and the reliability of the chip package structure are improved.

Realizations in accordance with the present invention therefore have been described in the context of particular embodiments. These embodiments are meant to be illustrative and not limiting. Many variations, modifications, additions, and improvements are possible. Accordingly, plural instances may be provided for components described herein as a single instance. Additionally, structures and functionality presented as discrete components in the exemplary configurations may be implemented as a combined structure or component. These and other variations, modifications, additions, and improvements may fall within the scope of the invention as defined in the claims that follow.

1. A chip package structure, comprising:
a package substrate, having a carrying surface and a back surface opposite to the carrying surface;
a chip, mounted on the carrying surface and electrically connected to the package substrate; and
a molding compound, applied over the carrying surface of the package substrate to cover the chip and a part of the package substrate, wherein an outline of a juncture between the molding compound and the package substrate is a smooth closed curve.

2. The chip package structure of claim 1, wherein the outline of the juncture between the molding compound and the package substrate is of a circular shape.

3. The chip package structure of claim 1, wherein the outline of the juncture between the molding compound and the package substrate is of an elliptical shape.

4. The chip package structure of claim 1, wherein the outline of the juncture between the molding compound and the package substrate is a polygon with rounded corners.

5. The chip package structure of claim 1, further comprising a plurality of solder balls mounted on the back surface of the package substrate and electrically connected to the chip via the package substrate.

6. The chip package structure of claim 1, further comprising a plurality of wires electrically connected to the chip and the package substrate.

7. The chip package structure of claim 6, wherein the molding compound further covers the wires.

8. The chip package structure of claim 1, further comprising a plurality of bumps electrically connected to the chip and the package substrate.

9. The chip package structure of claim 1, wherein the molding compound is a polymeric resin.
